(19) United States
(12) Patent Application Publication
(10) Pub. No.: US 2006/0132258 A1
(43) Pub. Date: Jun. 22, 2006

(54) Method and apparatus for large ratio radio frequency variable inductor and use in radio frequency power matching systems

(76) Inventor: John Seldon Ogle, Milpitas, CA (US)

Correspondence Address: John Seldon Ogle, 1472 Pashote Court, Milpitas, CA, 95035, US

(21) Appl. No.: 11/019,410

(22) Filed: Dec. 20, 2004

(51) Int. Cl. H03H 7/38

(52) U.S. Cl. 333/17.3; 333/32

(57) ABSTRACT

A radio frequency variable inductor with a high ratio of inductance variation to minimum inductance is provided by combining both conductive elements and ferromagnetic elements in an inductance variation assembly, which is rotatably mounted inside a coil. This variable inductor is combined with fixed capacitors and a variable transformer using a rotatable primary coil to provide a complete radio frequency match system.

### CROSS-REFERENCE TO RELATED APPLICATIONS

Not Applicable

### FEDERALLY SPONSORED RESEARCH

Not Applicable

### SEQUENCE LISTING OR PROGRAM

Not Applicable

### BACKGROUND OF THE INVENTION

This invention relates to high power radio frequency variable inductors, typically used in match systems which provide efficient power transfer by matching the electrical impedance of a radio frequency power source to a radio frequency load with different electrical impedance.

There are a number of viable approaches to high power radio frequency impedance matching for a varying impedance load. Each of these approaches has certain limitations or drawbacks in terms of cost, reliability, flexibility, size, speed of response, and ease of operation.

The most common approach uses two variable capacitors and a fixed inductor in an L or pi network. For low power operations air variable capacitors are commonly used. These air variable capacitors have two sets of interleaved metal plates that are rotated relative to each other to vary the area of overlap between the interleaved plates, and thus the capacitance. At high power levels the voltage gradient at the edges of the interleaved plates can cause arcing through the air.

For power operation above about a thousand watts, vacuum variable capacitors are commonly used, in which concentric interleaved metal plates are contained inside a vacuum enclosure to avoid the problem of high voltage arcing through air. These vacuum variable capacitors are expensive, fragile, slow in operation, and have a wear out failure mode caused by the large force on the bearings due to the differential pressure. Typically regular lubrication and other maintenance schedules are required to prevent binding of the bearings. The speed of response is slow because the tuning range requires multiple adjustment turns.

Variable inductors have been used in place of variable capacitors to provide the required impedance adjustment in matches. One variable inductance configuration uses a dual coil arrangement called a variometer, usually combining a spherically wound coil rotatably mounted inside another spherically wound coil, with the two coils connected in series. As the inner coil rotates relative to the outer coil, their mutual inductance varies, changing the inductance of the variometer. The problem of arcing between the coils limits the power capability in the same manner as arcing between the metal plates of an air variable capacitor. If the spacing between the coils is increased to increase the breakdown voltage and thus the power capability, the inductance variation ratio, defined as the inductance variation range divided by minimum inductance, is decreased. An additional disadvantage of the variometer is that the relative motion required between the coils for inductance adjustment requires either slip rings or flexible wires, and since the variable inductor is normally in the high current match output circuit, there are power loss and reliability problems associated with the required slip rings or flexible wires. Alternate variable inductor configurations use either a movable conductive volume or a movable ferromagnetic volume inside a coil to vary the inductance of the coil.

A movable conductive volume uses the “eddy current” effect to controllably reduce the inductance of the coil in a manner called “slug tuning”. A movable ferromagnetic volume inside the coil controllably increases the inductance of the coil. In either case, the variable inductance ratio is relatively small. One approach to increasing the inductance variation ratio in a slug tuning configuration is described in U.S. Pat. No. 5,952,896, IMPEDANCE MATCHING NETWORK, issued Sep. 14, 1999 to Mett et al., which uses multiple conductive vanes mounted to rotate about an axis parallel to the coil axis to move the multiple conductive vanes in between turns of a coil and out of the coil. While this multiple slug tuning arrangement increases the variable inductance ratio with rapid tuning, requiring only 180 degrees of rotation for the full adjustment range, it also has disadvantages. If the multiple conductive vanes are not insulated from each other, arcing can occur between ends of the coil through the multiple conductive vanes. An increased available volume is required for the multiple conductive vanes to rotate outside the coil. In addition, the radio frequency adjustment current concentrates around the edges of each of the multiple conductive vanes, which can result in an equivalent resistance large enough to result in multiple conductive vane heating and significant power loss. Another approach to the use of variable inductance in a radio frequency match is described in U.S. Pat. No. 6,816,029, RF MATCHING UNIT, issued Nov. 9, 2004 to Choi et al., which describes a variable inductor consisting of two coils with the inductance variation provided by relative motion between the coils, thus varying their mutual inductance. This arrangement does not provide a large adjustment ratio and has the additional disadvantage that flexible conductors are required in the high current path through the variable inductor.

### BRIEF SUMMARY OF THE INVENTION

The invention is a high power radio frequency variable inductor with a large inductance adjustment ratio, and means to use this variable inductor in a radio frequency match. This high power radio frequency variable inductor uses a fixed high current large conductor coil and a novel inductance adjustment assembly mounted to rotate about an axis inside this coil, perpendicular to the coil axis. This inductance adjustment assembly combines both conductive eddy current adjustment elements to reduce inductance of the coil and ferromagnetic adjustment elements to increase the inductance of the coil, all acting within a 90 degree rotation of the inductance adjustment assembly.

The objects of the invention are to provide an efficient high power radio frequency variable inductor with a large inductance ratio adjustment capability and rapid adjustment capability, with high reliability and low maintenance requirements, and to incorporate this variable inductor into a radio frequency match system.

### BRIEF DESCRIPTION OF THE SEVERAL VIEWS OF THE DRAWINGS

FIG. 1A is a plan view of the inductance adjustment assembly.

FIG. 1B is an elevation view of the inductance adjustment assembly.

FIG. 2A is a plan view of the variable inductor with the inductance adjustment assembly rotated for maximum inductance.

FIG. 2B is a plan view of the variable inductor with the inductance adjustment assembly rotated for minimum inductance.

FIG. 3A is a plan view of the variable inductor with the inductance adjustment assembly rotated to the midrange position, and with an external magnetic path assembly added.

FIG. 3B is a plan view of the external magnetic path assembly.

FIG. 4 is an electric schematic diagram of a complete radio frequency match, combining the variable inductor, a variable transformer, and fixed capacitors.

FIG. 5 is a plan view of the variable transformer primary coil assembly.

FIG. 6A is a plan view of a complete radio frequency match, with a combined transformer secondary coil and inductor coil, and with both the variable transformer primary coil assembly and the inductance adjustment assembly rotated to their mid-range positions.

FIG. 6B is a plan view of the complete radio frequency match of FIG. 6A, with the addition of an external magnetic return path assembly.

### DRAWING REFERENCE NUMERALS

10 Variable inductor
12 Variable inductor coil
14 Inductance adjustment assembly
16 Conductive adjustment element
18 Ferromagnetic adjustment element
20 Rotation shaft
22 External magnetic return path assembly
24 Complete radio frequency match
25 Radio frequency power source
26 Variable transformer primary coil
28 Primary coil compensation capacitor
30 Variable transformer primary coil assembly
32 Combined transformer secondary and inductor coil
34 Match output capacitor
36 Flexible power input wires
38 Rotational position drive assembly
40 Radio frequency load
   Detailed Description of the Variable Inductor

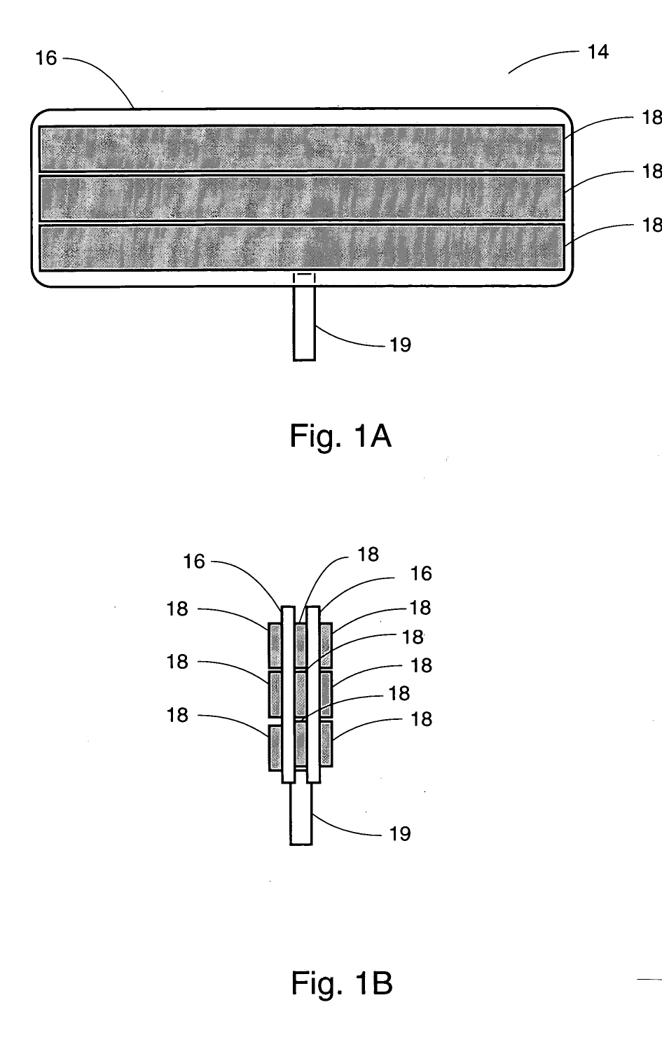

FIG. 1A is a plan view of inductance adjustment assembly 14, showing conductive adjustment element 16 and multiple units of ferromagnetic adjustment element 18. The rectangular shape of inductance adjustment assembly 14 increases the inductance variation ratio compared to a circular shape.

FIG. 1B is an elevation view of inductance adjustment assembly 14, showing multiple units of conductive adjustment element 16, with multiple units of ferromagnetic adjustment element 18 mounted to each unit of conductive adjustment element 16. Suitable materials for conductive adjustment element 16 include copper, aluminum, or any material with the periphery silver plated. A suitable material for ferromagnetic adjustment element 18 for frequencies in the 14 MHz frequency range is the M2 ferrite material available from National Magnetics Group, 1210 Win Drive, Bethlehem, Pa. 18017-7061.

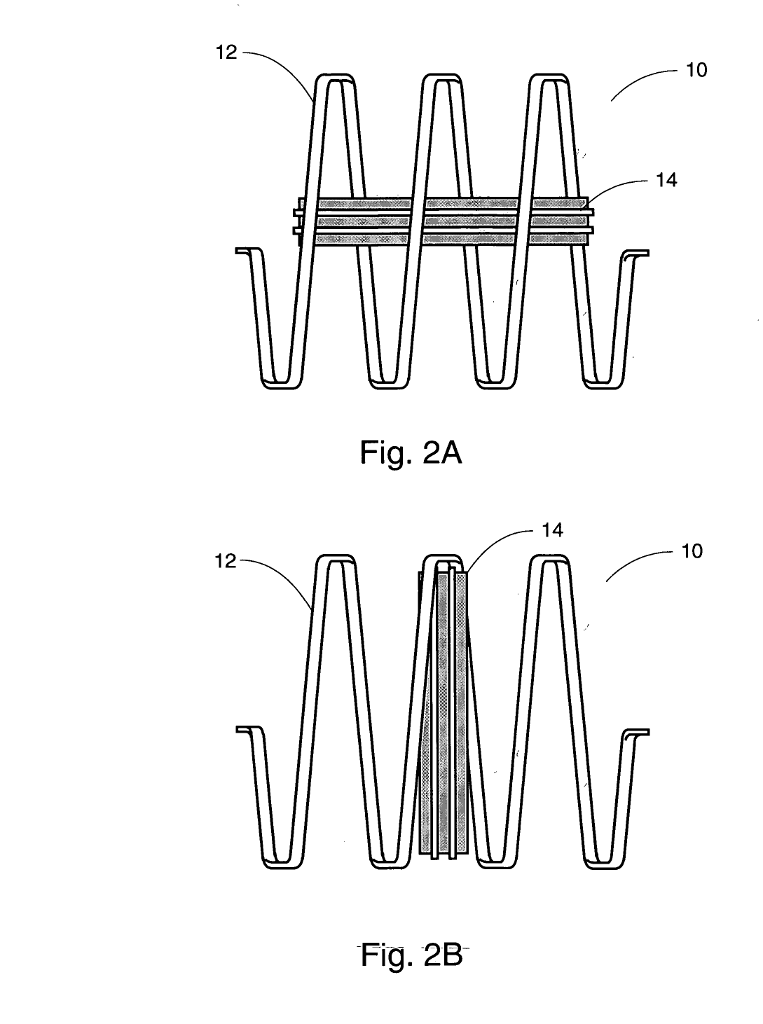

FIG. 2A is a plan view of variable inductor 10 with the plane of inductance adjustment assembly 14 rotated parallel to the axis of variable inductor coil 12 for maximum inductance. With this alignment each conductive adjustment element 16 has minimum effect in reducing the inductance of variable inductor 10, because the plane of each conductive adjustment element 16 is parallel with the magnetic flux of variable inductor coil 12, while each ferromagnetic adjustment element 18 has maximum effect in increasing the inductance of variable inductor 10, because each ferromagnetic adjustment element 18 is also parallel with the magnetic flux of variable inductor coil 12, reducing the magnetic reluctance through and increasing the inductance of variable inductor coil 12.

FIG. 2B is a plan view of variable inductor 10 with the plane of inductance adjustment assembly 14 rotated perpendicular to the axis of variable inductor coil 12. With this alignment each conductive adjustment element 16 blocks the magnetic path through variable inductor coil 12, reducing its inductance, while units of ferromagnetic adjustment element 18 have little effect on the inductance of variable inductor coil 12.

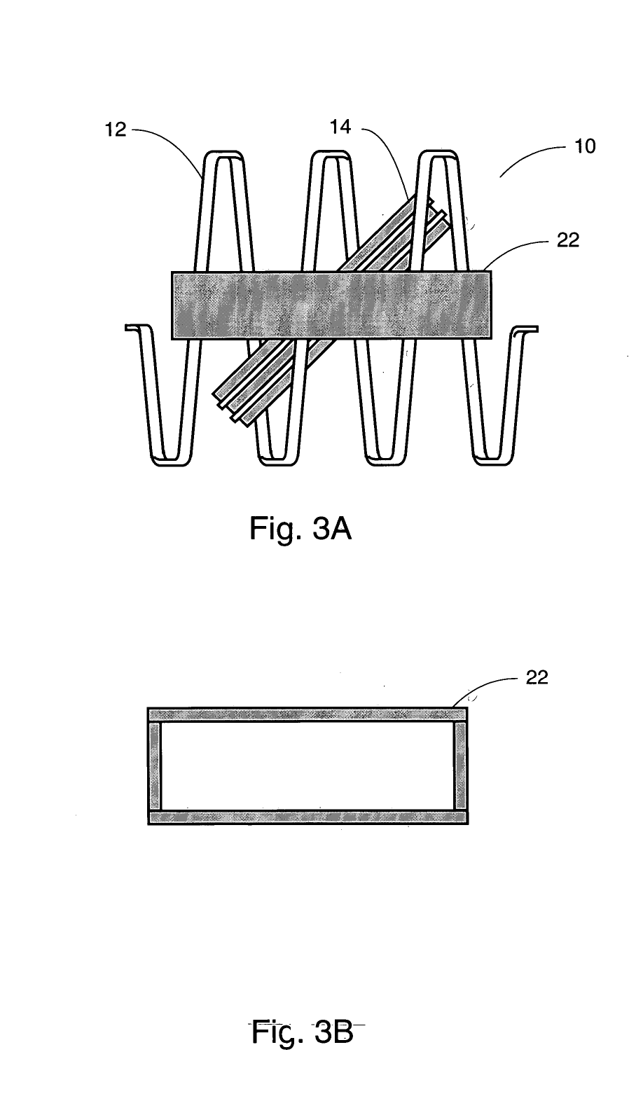

FIG. 3A is a plan view of variable inductor 10, with inductance adjustment assembly 14 rotated to its midrange position, and with the addition of external magnetic return path assembly 22. The addition of external magnetic return path assembly 22 reduces the magnetic reluctance of the portion of the magnetic path external to variable inductor coil 12 and increases both the inductance and the inductance variation ratio of variable inductor 10.

FIG. 3B is a plan view of external magnetic return path assembly 22. The function of this assembly is to reduce the magnetic reluctance of the return magnetic path external to variable inductor coil 12 to provide further increased inductance variation ratio.

Detailed Description—Variable Inductor Use in a Complete Radio Frequency Match

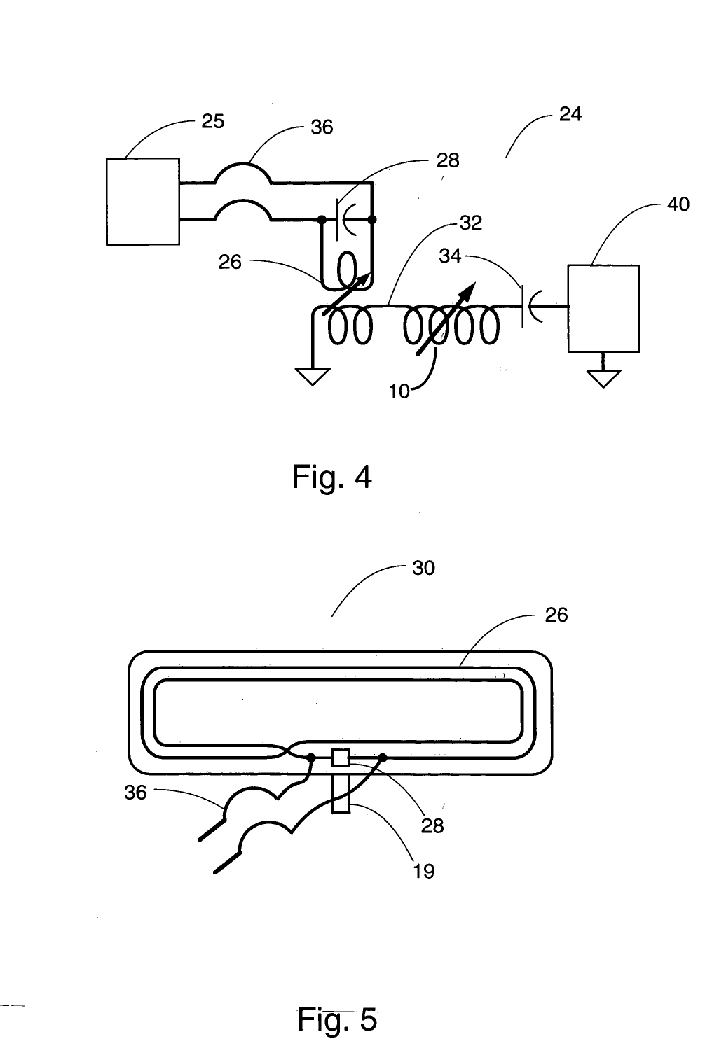

FIG. 4 is an electrical schematic diagram of complete radio frequency match 24. Radio frequency power source 25 is connected through flexible power input wires 36 to variable transformer primary coil assembly 22, which includes the parallel combination of variable transformer primary coil 26 and compensation capacitor 28. The function of compensation capacitor 28 is to form a parallel approximately resonant circuit with the leakage inductance of variable transformer primary coil 26, increasing the reactive component of the input impedance of variable transformer primary coil assembly 22. Relatively small current flows through flexible power input wires 36, since the output impedance of radio frequency power source 25 is typically 50 ohms resistive, and even at 10,000 watts, the current through flexible power input wires 36 is less than 15 amperes, so the rotation of variable transformer coil 24 through less than 90 degrees can be easily provided through flexible power input wires 36.

Radio frequency power is transformer coupled from variable transformer primary coil 26 to combined transformer secondary and inductor coil 32. Variable inductor 10 is adjusted to resonate with the series combination of match output capacitor 34 and the reactive component of radio frequency load 40. Radio frequency load 40 may be a plasma source, a transmitting antenna, or any other radio frequency load. Rotation of variable transformer primary coil assembly 30 provides matching adjustment, primarily for the resistive component of radio frequency load 40. The full range of adjustment for variable transformer primary coil assembly 30 and inductance adjustment assembly 14 are each provided by a 90 degree rotation about an axis perpendicular to the axis of combined transformer secondary and inductor coil 32. As a result, the adjustment can be rapid, typically in less than a tenth of a second. Additional advantages of this configuration include avoidance of high voltage gradients which could result in arcing, reduced wearout problems, lower cost, and smaller size than for presently available match systems.

FIG. 5 is a plan view showing variable transformer primary coil assembly 30, including the parallel connected combination of compensation capacitor 28 and variable transformer primary coil 26, and flexible power input wires 36.

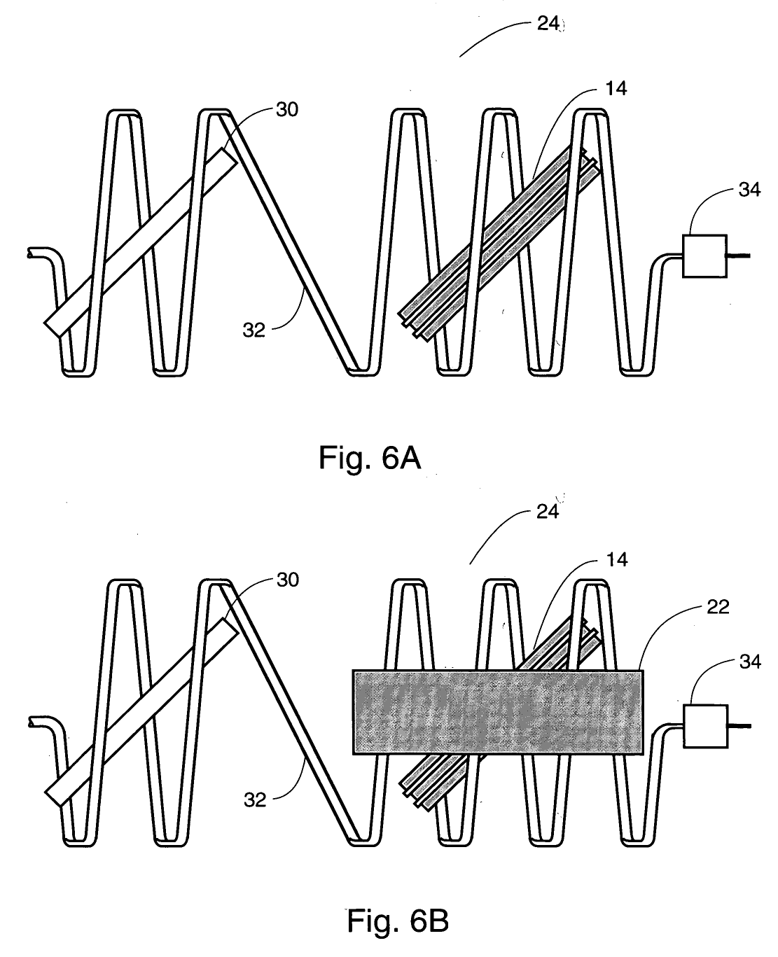

FIG. 6A is a plan view of complete radio frequency match 24, with combined transformer secondary and inductor coil 32, and with variable transformer primary coil assembly 30 and inductance adjustment assembly 14 both rotated to their mid range positions.

FIG. 6B is the plan view of complete radio frequency match of FIG. 6A, with the addition of external magnetic return path assembly 22.

Combined transformer secondary and inductor coil 32 should be capable of conducting currents as high as the hundreds of amperes, because the impedance of radio frequency load 40 may be both small and reactive.

1. A radio frequency variable inductor using a rotatable inductance adjustment assembly mounted inside a fixed coil, said rotatable inductance adjustment assembly incorporating both conductive and ferromagnetic elements.

2. The radio frequency variable inductor of claim 1, including multiple said rotatable inductance adjustment assemblies, each said rotatable inductance adjustment assembly incorporating both conductive and ferromagnetic elements.

3. The radio frequency variable inductor of claim 1, wherein:
The shape of the windings of said fixed coil and the shape of said rotatable inductance adjustment assembly are both approximately rectangular with rounded corners.

4. The radio frequency variable inductor of claim 1, further including ferromagnetic cores arranged to provide a reduced reluctance magnetic field return path external to said fixed coil.

5. The radio frequency variable inductor of claim 1, combined with a variable transformer and at least one capacitor to form a complete radio frequency match.

6. The radio frequency variable inductor of claim 1, combined with a variable transformer and at least one capacitor to form a complete radio frequency match, wherein a single fixed coil is used for both said variable inductor and as the secondary of said variable transformer.

7. The radio frequency variable inductor of claim 1, combined with a variable transformer and at least one capacitor to form a complete radio frequency match, and radio frequency sense circuitry to sense the voltage, current, and phase angle of the power at the input to said complete radio frequency match, and feedback control means, motors and motor drive means to adjust said variable inductor and said variable transformer for optimum matching to the output impedance of a radio frequency generator.
